(19) United States
(12) Patent Application Publication
(10) Pub. No.: US 2026/0088082 A1
(43) Pub. Date: Mar. 26, 2026

(54) SRAM BIT-CELL BASED BITLINE DETECTOR FOR ROBUST SELF-TIME

(71) Applicant: STMicroelectronics International N.V., Geneva (CH)

(72) Inventors: Kedar Janardan DHORI, Ghaziabad (IN); Tarun HANDA, Delhi (IN); Monika JINDAL, Greater Noida (IN)

(73) Assignee: STMicroelectronics International N.V., Geneva (CH)

(21) Appl. No.: 19/333,192

(22) Filed: Sep. 18, 2025

Related U.S. Application Data
(60) Provisional application No. 63/698,348, filed on Sep. 24, 2024.

(51) Int. Cl. G11C 11/419; G11C 11/412; H10B 10/00

(52) U.S. Cl. CPC G11C 11/419; G11C 11/412; H10B 10/12; H10B 10/18

(57) ABSTRACT

An integrated circuit includes a memory array including a plurality of main memory cells and a group of dummy memory cells. The group of dummy memory cells includes a dummy bitline and a timer dummy memory cell substantially identical to the memory cells and coupled to the dummy bitline. The group of dummy memory cells includes a modified dummy memory cell coupled to the dummy bitline and configured to output a detection signal indicating that a voltage on the dummy bitline has crossed a threshold value.

### BACKGROUND

### Technical Field

This present disclosure is related to computer memory, and more particularly, to signal timing of memories.

### Description of the Related Art

In some microcontroller systems, an always-on memory is utilized to ensure smooth wake up of the system. For most of the operational lifetime, this memory remains in a retention mode. For low power applications, it is beneficial to maintain the static power consumption of the memory at a low level.

All of the subject matter discussed in the Background section is not necessarily prior art and should not be assumed to be prior art merely as a result of its discussion in the Background section. Along these lines, any recognition of problems in the prior art discussed in the Background section or associated with such subject matter should not be treated as prior art unless expressly stated to be prior art. Instead, the discussion of any subject matter in the Background section should be treated as part of the inventor's approach to the particular problem, which, in and of itself, may also be inventive.

### BRIEF SUMMARY

Embodiments of the present disclosure provide a memory circuit including an array of memory cells and a group of dummy bit cells that are substantially identical to the memory cells. One of the dummy bit cells is modified to act as a detection device to detect when a dummy bitline has discharged below a threshold value. The detection device outputs a detection signal to a dummy bitline precharge circuit. The dummy bitline precharge circuit then outputs a sense amplifier enable signal that enables a sense amplifier to read data from one of the memory cells.

In one embodiment, a circuit includes a memory array including a plurality of main memory cells and a group of dummy memory cells. The group of dummy memory cells includes a dummy bitline, a timer dummy memory cell substantially identical to the memory cells and coupled to the dummy bitline, and a modified dummy memory cell coupled to the dummy bitline and configured to output a detection signal indicating that a voltage on the dummy bitline has crossed a threshold value.

In one embodiment, a method includes enabling a word line coupled to a selected memory cell of an array of memory cells and enabling a dummy word line coupled to a timer dummy memory cell of a group of dummy memory cells. The method includes sensing, with a modified dummy memory cell of the array of dummy memory cells, that a dummy bitline coupled to the timer dummy memory cell and the modified dummy memory cell has crossed a threshold voltage. The method includes providing, to a sense amplifier coupled to a bitline coupled to the selected memory cell, a sense amplifier enable signal responsive to the dummy bitline crossing the threshold voltage.

In one embodiment, an integrated circuit includes a microcontroller and an always-on circuit. The always-on circuit includes logic circuitry including a plurality of transistors having a first gate dielectric of a first thickness and a memory circuit. The memory circuit includes a plurality of memory cells each including a plurality of transistors having a second gate dielectric of a second thickness greater than the first thickness. The memory circuit includes a group of dummy memory cells including a load memory cell substantially identical to the memory cells and a modified dummy memory cell including a detection device configured to output a detection signal responsive to a voltage on a dummy bitline coupled to the timer dummy memory cell and the modified dummy memory cell crossing a threshold voltage.

### BRIEF DESCRIPTION OF THE SEVERAL VIEWS OF THE DRAWINGS

FIG. 1 is a block diagram of an integrated circuit, in accordance with one embodiment.

FIG. 2 is a schematic diagram of a memory circuit of an integrated circuit, in accordance with one embodiment.

FIG. 3 is a graph of signals related to a read operation of a memory, in accordance with one embodiment.

FIG. 4A is a schematic diagram of a timer dummy memory cell of a memory circuit, in accordance with one embodiment.

FIG. 4B is a layout of the timer dummy memory cell of FIG. 4A, in accordance with one embodiment.

FIG. 5A is a schematic diagram of a modified dummy memory cell of a memory circuit, in accordance with one embodiment.

FIG. 5B is a layout of the modified dummy memory cell of FIG. 5A, in accordance with one embodiment.

FIG. 6 is a schematic diagram of a modified dummy memory cell of a memory circuit, in accordance with one embodiment.

FIG. 7 is a flow diagram of a method for operating a memory circuit, in accordance with one embodiment.

### DETAILED DESCRIPTION

In the ensuing description, various specific details are illustrated aimed at enabling an in-depth understanding of the embodiments. The embodiments may be provided without one or more of the specific details, or with other methods, components, materials, etc. In other cases, known structures, materials, or operations are not shown or described in detail so that various aspects of the embodiments will not be obscured.

Reference to “an embodiment” or “one embodiment” in the framework of this description is meant to indicate that a particular configuration, structure, or characteristic described in relation to the embodiment is comprised in at least one embodiment. Hence, phrases such as “in an embodiment”, “in one embodiment”, or the like that may be present in various points of this description do not necessarily refer to one and the same embodiment. Moreover, particular conformations, structures, or characteristics may be combined in any adequate way in one or more embodiments.

In the following description, certain specific details are set forth in order to provide a thorough understanding of various disclosed embodiments. However, one skilled in the relevant art will recognize that embodiments may be practiced without one or more of these specific details, or with other methods, components, materials, etc.

Unless the context requires otherwise, throughout the specification and claims which follow, the word “comprise” and variations thereof, such as, “comprises” and “comprising” are to be construed in an open, inclusive sense, that is as “including, but not limited to.” Further, the terms “first,” “second,” and similar indicators of sequence are to be construed as interchangeable unless the context clearly dictates otherwise.

As used in this specification and the appended claims, the singular forms “a,” “an,” and “the” include plural referents unless the content clearly dictates otherwise. It should also be noted that the term “or” is generally employed in its broadest sense, that is as meaning “and/or” unless the content clearly dictates otherwise.

As used herein, “source/drain terminal” can refer to a source terminal of a transistor or a drain terminal of a transistor.

As used herein, the terms “bit cell” and “memory cell” may be used interchangeably.

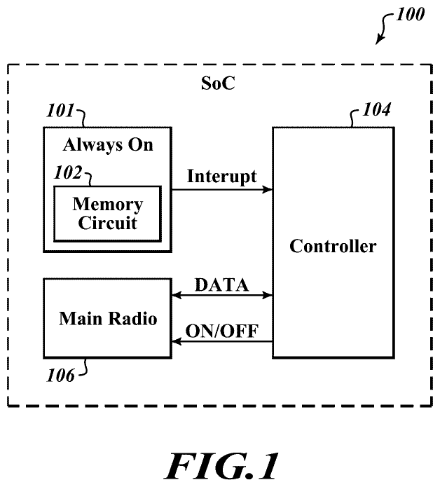

FIG. 1 is a block diagram of an integrated circuit 100, in accordance with one embodiment. The integrated circuit 100 includes an always-on circuit 101 with a memory circuit 102, a controller 104, and a main radio 106.

In one embodiment, the integrated circuit 100 is a system on chip (SoC), though other types of integrated circuits can be utilized without departing from the scope of the present disclosure. In one embodiment, the integrated circuit 100 is installed in a device that is part of an Internet of things.

For much of the operational lifetime of the integrated circuit 100, the integrated circuit 100 may be in a sleep mode or in a standby mode. In the sleep mode, the controller 104 and the main radio 106 are powered down. This is to ensure lower power consumption of the integrated circuit 100.

However, the integrated circuit 100 includes always-on circuitry 101. The always-on circuitry 101 is circuitry that remains powered or awake at all times. The always-on circuitry can include simple logic circuitry capable of performing basic control functions. However, the logic circuitry of the always-on circuitry 101 is not performed on the control functions that the microcontroller 104 can perform.

The always-on circuitry 101 includes a memory circuit 102. The memory circuit 102 includes an array of memory cells. The memory circuit 102 also includes peripheral circuitry such as read control circuitry, right control circuitry, decoders, sense amplifiers, and other circuitry for managing operation of the memory cells.

In one embodiment, the memory circuit 102 includes an SRAM array. In one embodiment, each SRAM memory cell is a six-transistor memory cell including a pair of cross coupled inverters and two access transistors. The memory array operates primarily in retention mode while other blocks of the integrated circuit 100 are sleep.

In one embodiment, because the SRAM array is an always-on array, it is beneficial to reduce power consumption of the memory cells in retention mode. Most particularly, it is beneficial to reduce leakage currents from the memory cells. In one embodiment, reduction of leakage currents is accomplished by implementing the transistors of the memory cells with a relatively large gate dielectric compared to other transistors of peripheral circuitry of the always-on circuit 102. Accordingly, the always-on circuits 101 includes peripheral transistors having a thin gate dielectric and memory cell transistors having a thicker gate dielectric than the peripheral transistors. In one embodiment, the thicker gate dielectric can be greater than or equal to double the thickness of the thin gate dielectric. In one embodiment, ultra-high threshold voltage transistors can be utilized for leakage reduction.

However, utilization of transistors of different gate dielectric thickness can result in problems in read and write operations of the memory due to process variations. For example, the self-time of an SRAM read operation can correspond to the time between the edge of a clock signal that initiates a read operation and the reading of data, corresponding to completion of the read operation. As an example, when a read operation is to be performed, a rising edge of the clock signal may trigger the rising edge of a word line enable signal being provided to the row of a selected memory cell. True and false bitlines coupled to the memory cell may be pre-charged. A sense amplifier coupled to the true and false bitlines reads data from the memory cell once the true and false bitlines have charged to a desired voltage differential. More particularly, a sense amplifier enable signal is provided to the sense amplifier to trigger reading of data.

One possible solution for generating the sense amplifier enable signal is to include a plurality of dummy memory cells adjacent to the memory cells of the main memory array and to generate the sense amplifier enable signal by detecting discharging of dummy bitlines coupled to the dummy memory cells. The dummy memory cells correspond to replicas of the main memory cells, implemented with the thicker gate oxide. The column of dummy memory cells is coupled to true and false dummy bitlines and one or more dummy word lines. A discharge detection circuitry is implemented in the peripheral circuitry. The dummy word line goes high at the same time that the word line goes high and either the true dummy bitline or the false dummy bitline begin to discharge. More particularly, the dummy memory is pre-programmed to discharge any one dummy bitline of the two and the discharge detection circuitry is implanted for that dummy bit line. The discharge detection circuitry detects when the dummy bitlines have discharged to a selected threshold. When the dummy bitlines have discharged to the selected threshold, the discharge detection circuitry causes the sense amplifier enable signal to be output. At the end of the cycle, the dummy bitline is again preset to start the next operation. Accordingly, one of the dummy bitlines discharges while the other remains stable.

One problem with this potential solution is that the discharge detection circuitry is implemented with the thin gate oxide transistors, while the dummy memory cells and the main memory cells are implemented with the thicker gate oxide transistors. There is potential that improper timing of the sense amplifier enable signal can occur based on process variations.

Embodiments of the present disclosure overcome these drawbacks by implementing the discharge detection device in the dummy memory cells. More particularly, one of the dummy memory cells is modified to act as a detection device that detects discharge of the dummy bitline. Because the discharge detection device is implemented in the dummy memory cells, the discharge detection device is implemented with transistors having the thicker gate oxide. The result is that the discharge detection device can trigger the sense amplifier enable signal in a manner substantially immune from process variations. Further details regarding the discharge detection device are provided below.

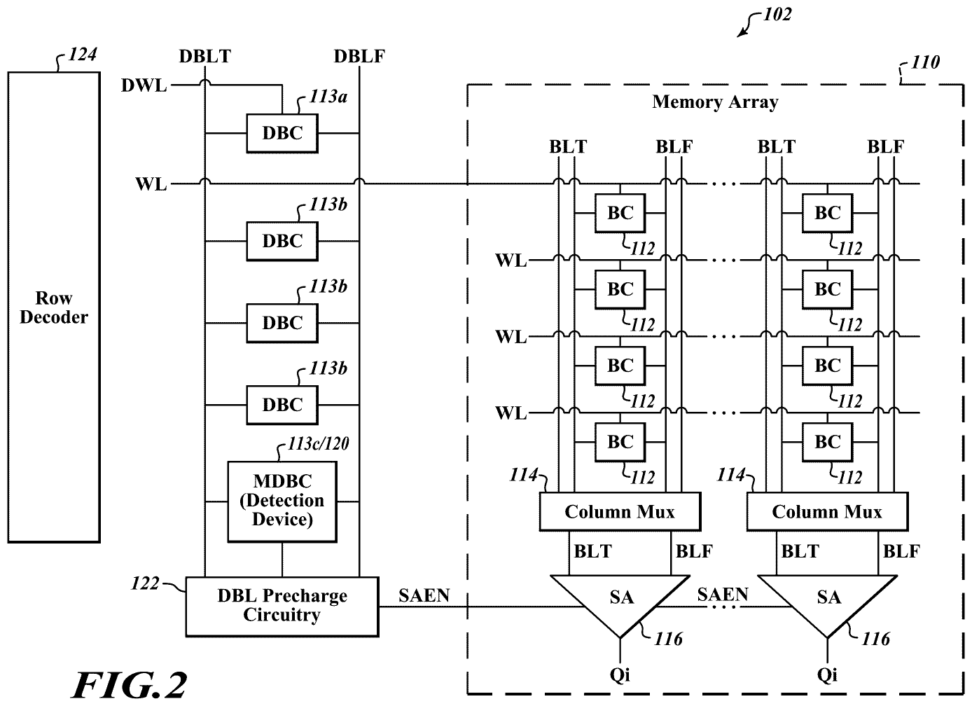

FIG. 2 is a schematic diagram of a memory circuit 102, in accordance with one embodiment. The memory circuit 102 includes a memory array 110. The memory array 110 includes an array of SRAM bit cells (BC) 112. For simplicity, FIG. 2 illustrates two columns of memory cells 112. Each column of memory cells 112 includes four memory cells. In practice, the memory array 110 may include a large number of columns of memory cells 112. Each column of memory cells 112 may include a large number of memory cells. The memory cells 112 are implemented utilizing transistors having the thicker gate oxide, as described previously.

Each column of memory cells 112 is coupled to a pair of bitlines. Or particularly, each column of memory cells 112 is coupled to a true bitline (BLT) and the false bitline (BLF). Accordingly, each memory cell of a column is coupled to both the true bitline and the false bitline.

Each column of memory cells 112 is coupled to a column the multiplexer 114. The call multiplexer 114 is utilized to select a column of memory cells for a read or a write operation. Accordingly, the column multiplexers 114 may each include access transistors or other gates or devices that enable selection of a column of memory cells for a read or write operation.

Each row of memory cells is coupled to a word line (WL). Each word line enable selection of a row of memory cells for a read or a write operation. Accordingly, a selected row and a selected column corresponds to a selected memory cell 112.

Each column is coupled to a sense amplifier (SA) 116. More particularly, the true and false bitline of each column is coupled to the sense amplifier 116 via the column multiplexer 114.

In one embodiment, prior to a read operation, the true bitline and the dummy bitline are precharged to VDD. During a read operation of a selected memory cell 112, either the true bitline or the false bitline is discharged, based on the data in the memory cell, to create a differential voltage (voltage difference between BLT and BLF). It is beneficial to cause the sense amplifier 116 to read the data value Qi from a memory cell 112 once the true or false bitline has discharged to a sufficient differential voltage. However, if the discharge time is too small, then the differential voltage may not be large enough for a reliable read operation once the sense amplifier 116 is enabled. If the discharge time is too large, then the differential voltage may unduly large, resulting in unwanted power consumption. Accordingly, it is beneficial to control the timing of the sense amplifier enable signal SAEN to ensure that the differential voltage is within a selected range.

The memory circuit 102 includes a plurality of dummy bit cells (DBC) 113. The dummy bit cells 113 are arranged in a column. The dummy bit cells 113 are each coupled to a true dummy bitline (DBLT) and a false dummy bitline (DBLF). The true dummy bitline and the false dummy bitline are coupled to dummy bitline precharge circuitry 122. One or more of the dummy bit cells is coupled to a dummy word line (DWL). The dummy bit cells 113 are replicas of the bit cells 112 and are implemented with the thick gate oxide. Further details regarding the dummy bit cells 113 will be described below.

The memory circuit 102 also includes peripheral circuitry. The peripheral circuitry includes dummy bitline precharge circuitry 122 and a row decoder 124. The peripheral circuitry is implemented using transistors having the thin gate dielectric. The dummy bitline precharge circuitry 122 is coupled to the true and false dummy bitlines and is configured to precharge the true and false dummy bitlines and to generate the sense amplifier enable signal. The row decoder 124 is coupled to the word lines and the dummy word line and is configured to selectively enable the word lines and the dummy word line.

The column of dummy bit cells 113 includes one or more discharge/timer dummy bit cells 113a. The timer bit cell 113a stores a known data value and is utilized in generating the sense amplifier enable signal, as will be described in more detail below. The timer dummy bit cells 113a are substantially identical to the bit cells 112 of the memory array 110.

The column of dummy bit cells includes dummy bit cells 113b. The dummy bit cells 113b are identical to the timer dummy bit cells 113a. The dummy bit cells 113b are not utilized to store dummy data like the timer dummy bit cells 113a. However, in one embodiment all of the dummy bit cells 113b may be timer bit cells 113a. The dummy bit cells 113b may be termed “load” dummy bit cells. One difference between the load dummy bit cells 113b and the timer dummy bit cells 113a is that the word line terminals (control gates of the access transistors) of the load dummy bit cells 113b are connected to ground.

The column of dummy bit cells includes a modified dummy bit cell 113c. The modified dummy bit cell 113c also acts as a detection device 120. The modified dummy bit cell 113c is identical to the dummy bit cells 113a and 113b, except that some interconnections have been modified or removed so that the modified dummy bit cell 113c can function as the detection device 120. The modified dummy bit cell 113c includes the six transistors of the other dummy bit cells 113a and 113b and the memory cells 112. However, one or more interconnections have been modified. The detection device 120 is coupled to the dummy bitline precharge circuitry 122 and provides a detection signal to the dummy bitline precharge circuitry 122, as will be described in more detail below.

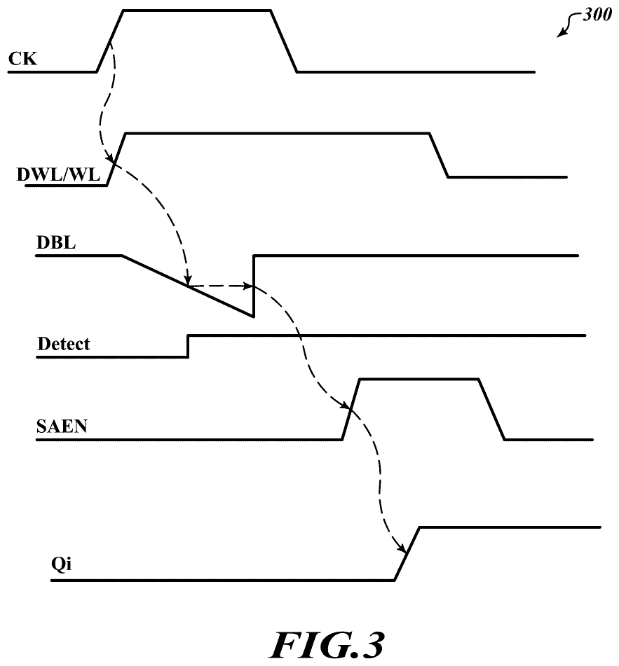

FIG. 3 is a graph 300 illustrating signals associated with a read operation of a memory cell, according to one embodiment. The description of the graph 300 will also be made with reference to the memory circuit 102 of FIG. 2.

The graph 300 includes a clock signal CK and a word line signal/dummy word line signal WL/DWL. To implement a read operation of a selected memory cell 112, the word line signal WL/DWL goes high responsive to a rising edge of the clock signal CK. Accordingly, a selected word line WL and the dummy word line WL go high at the rising edge of the clock signal CK. Though not shown in FIG. 2, the memory circuit 102 can include a clock generator that generates the clock signal CK. Alternatively, the clock generator may be external to the memory circuit 102.

When the dummy word line goes high, the timer dummy bit cell 113a is enabled. The dummy bitlines begins to discharge, as can be seen in FIG. 3. The modified dummy bit cell 113c, acting as a detection device 120, detects when the dummy bitlines have discharged to a threshold value. The detection device 120 outputs a detection signal indicating that the dummy bitlines have discharged to a threshold value.

The dummy bitline precharge circuitry 122 receives the detection signal from the detection device 120. The dummy bitline precharge circuitry 122 outputs the sense amplifier enable signal SAEN responsive to the detection signal and after a selected delay. The sense amplifier enable signal is provided to the sense amplifiers 116. The sense amplifiers 116 read the data value Qi from the selected memory cell 112.

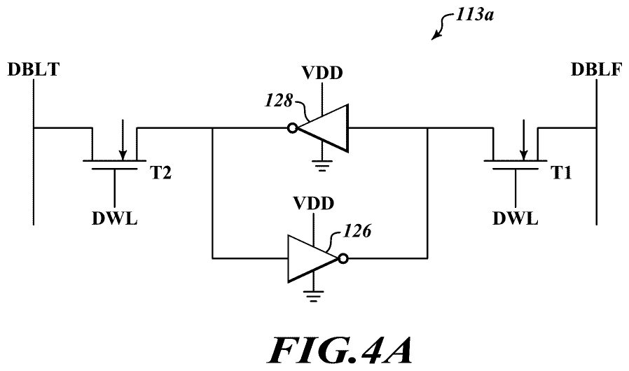

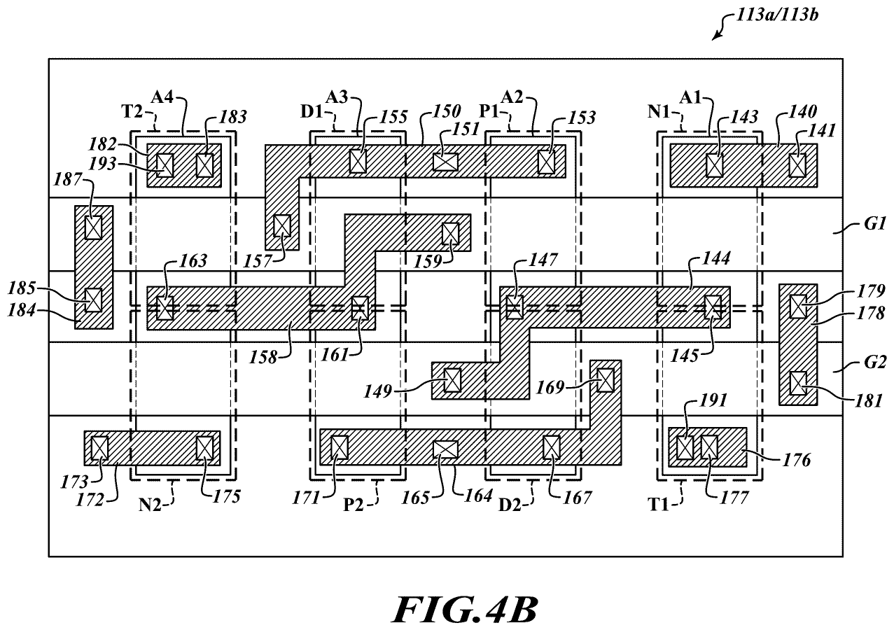

FIG. 4A is a schematic diagram of a timer dummy bit cell 113a, according to one embodiment. The memory cells 112 are substantially identical to the timer dummy bit cell 113a. The dummy bit cell 113a includes an inverter 126 and an inverter 128 cross coupled together. In particular, the output of the inverter 126 is coupled to the input of the inverter 128. The output of the inverter 128 is coupled to the input of the inverter 126. Each of the inverters 126 and 128 includes a PMOS transistor and an NMOS transistor. Each of the inverters receives VDD at a high supply terminal and ground and a low supply terminal.

The dummy bit cell 113a includes an access transistor T1 coupled between the output of the inverter 126 and the false dummy bitline DBLF. The dummy bit cell 113a includes an access transistor T2 coupled between the output of the inverter 128 and the true dummy bitline DBLT. In the example of FIG. 4A, the output of the dummy bit cell 113a is the output of the inverter 128. Said another way, the output of the inverter 128 is the true data storage node of the dummy bit cell 113a.

FIG. 4B is a simplified layout of the dummy bit cell 113a of FIG. 4A, according to one embodiment. The layout illustrates four active areas A1-A4. The active areas correspond to active areas of a semiconductor substrate. The layout illustrates two gate strips, G1 and G2. The gate strips G1 and G2 overlie each of the active areas A1-A4. The gate strips correspond to gate metals that overlie the semiconductor substrate. A transistor is formed at each location where one of the gate strips overlies one of the active regions. N-channel transistors are formed at the active areas A1 and A4. P-channel transistors are formed at the active areas A2 and A3.

An N-channel transistor N1 of the inverter 126 is formed at the overlap of G1 and A1. A P-channel transistor P1 of the inverter 126 is formed at the overlap of G1 and A2. An N-channel transistor N2 of the inverter 128 is formed at the overlap of G2 and A4. A P-channel transistor P2 of the inverter 128 is formed at the overlap of G2 and A3. The transistor T1 is formed at the overlap of G2 and A1. The transistor T2 is formed at the overlap of G1 and A4. A first P-channel dummy transistor D1 is formed at the overlap of G1 and A3. A second P-channel dummy transistor D2 is formed at the overlap of G2 and A2.

Metal tracks 140, 144, 150, 158, 164, 172, 176, 178, 182, and 184 are formed the active regions in the gate strips. In practice, the metal tracks are formed in an interlevel dielectric layer above the substrate and the gate strips.

Ground voltage is applied to the metal track 140 via a contact 141. Ground is applied to the source terminal of the transistor N1 via a contact 143. The drain terminals of the transistors N1 and P1 are coupled together by the metal track 144 and the contacts 145 and 147. More particularly, the contact 145 connects the metal track 144 to the drain terminal of the transistor N1, the contact 147 connects the metal track 144 to the drain terminal of the transistor P1, and a contact 149 connects the metal track 144 to the gate terminal of the transistors N2 and P2. Accordingly, the metal track 144 corresponds to the output of the inverter 126 and to the input of the inverter 128.

The metal track 150 receives VDD via the contact 151. VDD is then applied to the source terminal of the transistor P1 via a contact 153, to the source terminal of the transistor D1 via the contact 155, and to the gate terminal of the transistor D1 via the contact 157.

The drain terminals of the transistors N2 and P2, as well as the gate terminal of the transistors P1 and N1, are coupled together by the metal track 158 in the contacts 159, 161, and 163. More particularly, the metal track 158 is coupled to the gate terminals of the transistors P1 and N1 via a contact 159, to the drain terminal of the transistor P2 via the contact 161, and to the drain terminal of the transistor N2 via the contact 163.

The metal track 164 receives VDD via the contact 164. VDD is supplied to the source terminal of the transistor P2 via a contact 171, the source terminal of the transistor D2 via the contact 167, and to the gate terminal of the transistor D2 via the contact 169.

The metal track 172 receives ground voltage via the contact 173. Ground voltage is applied to the source terminal of the transistor N2 via the contact 175.

The metal track 176 is coupled to the false dummy bitline via the contact 177. The metal track 176 is coupled to a source/drain terminal of the transistor T1 via a contact 191.

The metal track 178 is coupled to the dummy word line via the contact 179. The metal track 178 is coupled to the gate of the transistor T1 via the contact 181.

The metal track 182 is coupled to the true dummy bitline via the contact 183. The source/drain terminal of the transistor T2 is coupled to the metal track 182 by the contact 193.

The metal track 184 is coupled to the dummy word line by the contact 185. The metal track 184 is coupled to the gate terminal of the transistor T2 by the contact 187.

FIG. 4B gate strips G1 and G2 as substantially unbroken strips. However, in practice, there are various breaks in the gate strips G1 and G2 to ensure that the gate terminals of various of the transistors are not shorted together. For example, the gate strips G1 is broken between the active area A2 and the active area A3 and between the active area A3 and the active area A4. The result is that the gate terminal of the transistors P1 and D1 are not shorted together and the gate terminals of the transistors D1 and T2 are not shorted together. The gate strips G2 is broken between the active areas A1 and A2 and between the active areas A2 and A3. The result is that the gate terminals of the transistors T1 and D2 are not shorted together and the gate terminals of the transistors P2 and D2 are not shorted together.

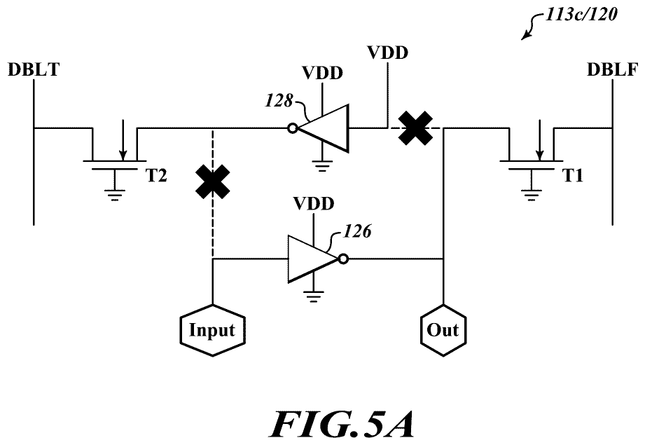

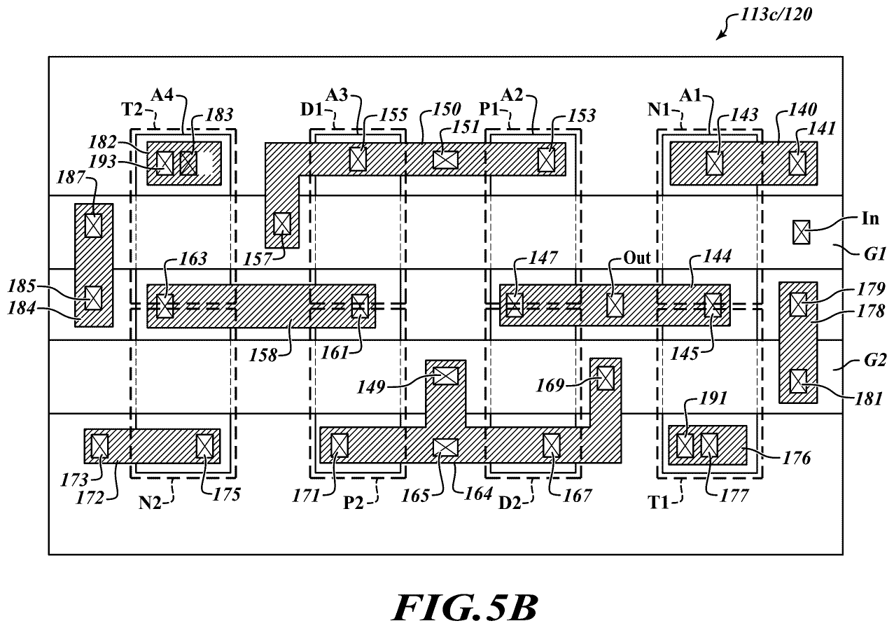

FIG. 5A is a schematic diagram of a modified dummy bit cell 113c, corresponding to a detection device 120, in accordance with one embodiment. The modified dummy bit cell 113c includes the inverters 126 and 128 and the transistors T1 and T2. However, the dummy bit cell 113c is modified with respect to the dummy bit cell 113a in that the output of the inverter 126 is not coupled to the input of the inverter 128, and the output of the inverter 128 is not coupled to the input of the inverter 126.

The inverter 126 acts as a detection device 120. In particular, the input of the inverter 126 receives the true dummy bitline voltage as an input. Initially, the true dummy bitline is at VDD, and the output of the inverter 126 is ground. As the true dummy bitline discharges, eventually the voltage of the true dummy bitline crosses the threshold value at which the output of the inverter 126 switches from ground to VDD. Accordingly, the output of the inverter 126 is a detection signal. When the detection signal goes high, the sense amplifier enable signal also goes high, after a selected delay. The value of the threshold can be selected based on the size and other characteristics of the transistors that make up the inverter 126.

The modifications to the modified dummy bit cell 113c can be implemented by removing one or more contacts or by modifying or removing one or more metal tracks. This can accomplish the removal of the cross coupling between the inverters 126 and 128.

FIG. 5B is a layout of the modified dummy bit cell 113c. The layout of the dummy bit cell 113c is substantially similar to the layout of the dummy bit cell 113a of FIG. 4B, apart from modifications that result in the modified dummy bit cell shown in FIG. 5A. In particular, the metal tracks 144 and 164 are modified so that the contact 149 is now coupled to the metal line 164 rather than to the metal lines 144. The result is that the drain terminals of the transistors N1 and P1 are no longer coupled to the gate terminal of the transistors N2 and P2. Furthermore, the gate terminals of the transistors N2 and P2 receive VDD via the contact 149 and the metal track 164.

The metal line 158 has been modified with respect to the layout of the dummy bit cell 113a. In particular, the contact 159 has been removed. The result is that the drain terminals of the transistors P2 and N2 are no longer coupled to the gate terminals of the transistors P1 and N1. In other words, the output of the inverter 128 is not coupled to the input of the inverter 126.

An input contact has been added at the gate of the transistors N1 and P1. The input contact couples the true dummy bitline to the gates of the transistors N1 and P1. In other words, the input of the inverter 126 (i.e., the detection device) is coupled to the true dummy bitline.

An output contact has been added to the metal track 144. The output contact is coupled to the drain terminals of the transistors P1 and N1 via the metal track 144 and the contacts 145 and 147. In other words, the output of the inverter 126 is the output of the detection device 120. The inverter 128 acts as a dummy inverter.

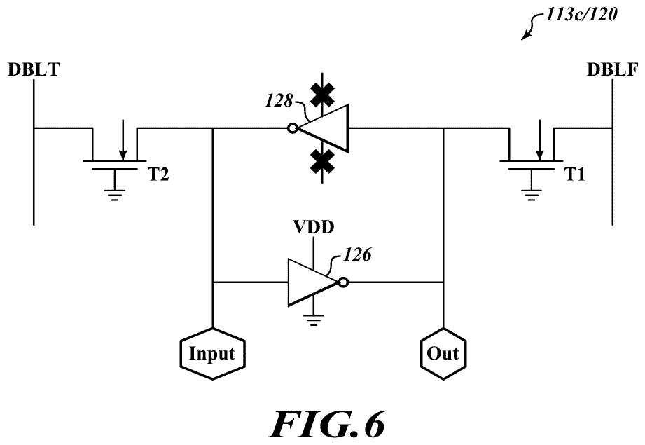

FIG. 6 is a schematic diagram of a modified dummy bit cell 113c/detection device 120, in accordance with one embodiment. The modified dummy bit cell 113c is substantially identical to the dummy bit cell 113a, except that the supply terminals of the inverter 128 no longer receive VDD and ground. The result is that the inverter 128 becomes a nonfunctioning dummy inverter. The inverters 128 and 126 are cross coupled, but as the inverter 128 longer receives VDD and ground, the inverter 128 no longer has any effect on the inverter 126. The input of the inverter 126 is coupled to the true dummy bitline and acts as the input of the detection device 120. The output of the inverter 126 provides the detection signal.

In one embodiment, the layout of the modified dummy bit cell 113c of FIG. 6 is substantially similar to the layout of the dummy bit cell 113a of FIG. 4B, except that the contact 171 is not present and the contact 175 is not present. The result is that the source terminal of the transistor N2 of the inverter 128 does not receive ground voltage and the source terminal of the transistor P2 of the inverter 128 does not receive VDD.

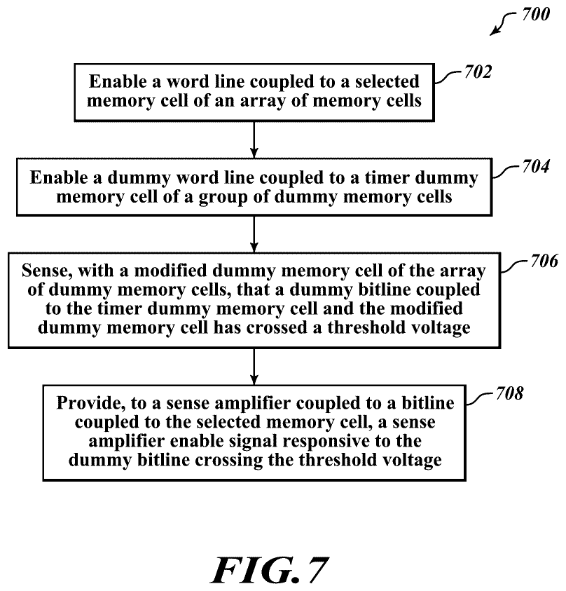

FIG. 7 is a flow diagram of a method 700 for operating a memory circuit, in accordance with one embodiment. The method 700 can utilize components, systems, and processes described in relation to FIGS. 1-6. At 702, the method 700 includes enabling a word line coupled to a selected memory cell of an array of memory cells. At 704, the method 700 includes enabling a dummy word line coupled to a timer dummy memory cell of a group of dummy memory cells. At 706, the method 700 includes sensing, with a modified dummy memory cell of the array of dummy memory cells, that a dummy bitline coupled to the timer dummy memory cell and the modified dummy memory cell has crossed a threshold voltage. At 708, the method 700 includes providing, to a sense amplifier coupled to a bitline coupled to the selected memory cell, a sense amplifier enable signal responsive to the dummy bitline crossing the threshold voltage.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A circuit, comprising:
a memory array including a plurality of main memory cells;
a group of dummy memory cells including:
a dummy bitline;
a timer dummy memory cell substantially identical to the memory cells and coupled to the dummy bitline;
a modified dummy memory cell coupled to the dummy bitline and configured to output a detection signal indicating that a voltage on the dummy bitline has crossed a threshold value.

2. The circuit of claim 1, wherein the timer dummy memory cell and the modified dummy memory cell include a same number of transistors.

3. The circuit of claim 2, wherein the timer dummy memory cell includes a first inverter and a second inverter cross-coupled together, wherein the modified dummy memory cell includes a third inverter and a fourth inverter, wherein an input of the third inverter is electrically isolated from an output of the fourth inverter.

4. The circuit of claim 3, wherein the third inverter is a detection device having an input coupled to the dummy bitline and an output that provides the detection signal.

5. The circuit of claim 2, wherein the timer dummy memory cell includes a first inverter and a second inverter cross-coupled together, wherein the modified dummy memory cell includes a third inverter and a fourth inverter, wherein a first supply input of the fourth inverter is floating.

6. The circuit of claim 5, wherein a second supply input of the fourth inverter is floating.

7. The circuit of claim 1, comprising a dummy bitline precharge circuit configured to precharge the dummy bitline.

8. The circuit of claim 7, wherein the dummy bitline precharge circuit is configured to receive the detection signal.

9. The circuit of claim 8, comprising a sense amplifier coupled to a column of the main memory cells and to the dummy bitline precharge circuit, wherein the dummy bitline precharge circuit is configured to output a sense amplifier enable signal to the sense amplifier responsive to receiving the detection signal.

10. The circuit of claim 1, comprising:
a wordline coupled to a row of the main memory cells; and
a dummy wordline coupled to the timer dummy memory cell.

11. A method, comprising:
enabling a word line coupled to a selected memory cell of an array of memory cells;
enabling a dummy word line coupled to a timer dummy memory cell of a group of dummy memory cells;
sensing, with a modified dummy memory cell of the array of dummy memory cells, that a dummy bitline coupled to the timer dummy memory cell and the modified dummy memory cell has crossed a threshold voltage; and
providing, to a sense amplifier coupled to a bitline coupled to the selected memory cell, a sense amplifier enable signal responsive to the dummy bitline crossing the threshold voltage.

12. The method of claim 11, wherein the timer dummy memory cell is substantially identical to the memory cells.

13. The method of claim 11, comprising reading data from the memory cell with the sense amplifier responsive to receiving the sense amplifier enable signal.

14. The method of claim 13, wherein the timer dummy memory cell and the modified dummy memory cell are in a column of dummy memory cells.

15. The method of claim 11, comprising:
outputting, from an inverter of the modified dummy memory cell having an input coupled to the dummy bitline, a detection signal responsive to the dummy bitline crossing the threshold voltage; and
receiving, with a dummy bitline precharge circuit, the detection signal; and
outputting, from the dummy bitline precharge circuit, the sense amplifier enable signal to the sense amplifier responsive to receiving the detection signal.

16. The method of claim 15, comprising maintaining a supply input of a second inverter of the modified dummy memory cell in a floating state.

17. The method of claim 15, comprising electrically isolating the input of the first inverter from an output of a second inverter of the modified dummy memory cell.

18. An integrated circuit, comprising:
a microcontroller;
an always-on circuit including:
logic circuitry including a plurality of transistors having a first gate dielectric of a first thickness;
a memory circuit including:
a plurality of memory cells each including a plurality of transistors having a second gate dielectric of a second thickness greater than the first thickness; and
a group of dummy memory cells including a load memory cell substantially identical to the memory cells and a modified dummy memory cell including a detection device configured to output a detection signal responsive to a voltage on a dummy bitline coupled to the timer dummy memory cell and the modified dummy memory cell crossing a threshold voltage.

19. The integrated circuit of claim 18, comprising a microcontroller coupled to the always-on circuit, wherein the always-on circuit is configured to output an interrupt to wake up the microcontroller.

20. The integrated circuit of claim 19, comprising a radio coupled to the microcontroller.
